(19) United States
(12) Patent Application Publication
(10) Pub. No.: US 2013/0160806 A1
(43) Pub. Date: Jun. 27, 2013

(54) THERMOELECTRIC DEVICE AND FABRICATING METHOD THEREOF

(71) Applicant: Electronics and Telecommunications Research, Daejeon (KR)

(72) Inventors: Young Sam PARK, Daejeon (KR); Moon Gyu Jang, Daejeon (KR); Younghoon Hyun, Seoul (KR); Taehyoung Zyung, Daejeon (KR)

(73) Assignee: Electronics and Telecommunications Research Institute, Daejeon (KR)

(21) Appl. No.: 13/651,618

(22) Filed: Oct. 15, 2012

(30) Foreign Application Priority Data
Dec. 22, 2011 (KR) 10-2011-0140232

(51) Int. Cl. H01L 35/30; H01L 35/34

(52) U.S. Cl. 136/205; 136/201

(57) ABSTRACT

Disclosed are a thermoelectric device and a fabricating method thereof. The thermoelectric device includes: a substrate; a heat absorbing part, a leg, and a heat radiating part formed on the substrate; and a heat radiating material formed between the substrate and the heat radiating part to radiate heat transferred from the heat radiating part.

### CROSS-REFERENCE TO RELATED APPLICATIONS

This application is based on and claims priority from Korean Patent Application No. 10-2011-0140232, filed on Dec. 22, 2011, with the Korean Intellectual Property Office, the disclosure of which is incorporated herein in its entirety by reference.

### TECHNICAL FIELD

The present disclosure relates to a thermoelectric device and a fabricating method thereof, and more particularly, to a thermoelectric device and a fabricating method thereof capable of improving heat radiation efficiency of a heat radiating part by directly or indirectly connecting heat radiating materials capable of effectively radiating heat to the heat radiating part.

### BACKGROUND

Recently, people all around the world have benefit from several electronic devices to which a nano process is applied, due to the fast development of a semiconductor process. As an example, there are ‘iPhone’ (that is a smart phone from Apple Inc.) in which NAND flash products fabricated based on a semiconductor design rule of several tens of nanometers are installed, and a personal computer in which a central process unit (CPU), a dynamic random access memory (DRAM) are installed.

Many scientists have proactively and intensively research many devices using a nanowire in the world of nanotechnology. As a result, new research themes such as carbon nanotube, and the like, have rapidly emerged. Accordingly, a comprehensive understanding and many researches into the world of nanotechnology have been conducted based on theoretical studies and experiments, and the like, in device research using the nanowire. One of the representative applications may include a thermoelectric device.

The thermoelectric device, which is a device to convert heat energy into electric energy, is one of the representative technical fields that can meet both of energy and eco-friendly policies. The thermoelectric device may use any type of heat on Earth, such as solar heat, waste heat for vehicles, terrestrial heat, body heat, radioactive heat, and the like, as the energy source thereof.

A thermoelectric effect is first discovered by Thomas Seebeck in the 1800s. Thomas Seebeck first found the thermoelectric effect by verifying that after connecting bismuth with copper and disposing a compass therebetween, current is induced due to a temperature difference generated at the time of heating one side of the bismuth and a magnetic field generated due to the induced current moves the compass.

FIG. 1 is a diagram showing a configuration of a generally used thermoelectric device.

Referring to FIG. 1, the thermoelectric device includes a heat absorbing part 110, a leg 120, and a heat radiating part 130. In this configuration, the leg 120 is configured of a p-type leg 120p and an n-type leg 120n.

The heat absorbing part 110 serves to absorb an external heat source, the leg 120 serves to transfer the heat absorbed through the heat absorbing part 110 to the heat radiating part 130, and the heat radiating part 130 serves to radiate the heat transferred from the leg to the outside.

Holes in the p-type leg 120p move toward the heat radiating part 130 from the heat absorbing part 110 due to a temperature difference between the heat absorbing part 110 and the heat radiating part 130 and electrons in the n-type leg 120n move toward the heat radiating part 130 from the heat absorbing part 110. Current flows counterclockwise according to the movement of the holes and the electrons.

Generally, a figure of merit (ZT) value is used as an index indicating thermoelectric efficiency. The ZT value is in proportion to a square of a Seebeck coefficient value and electric conductivity and is in inverse proportion to thermal conductivity. These terms largely depend on inherent features of materials. In case of metal, the Seebeck coefficient value is very low as several uV/K, and the electric conductivity and the thermal conductivity have a proportional relationship by Wiedemann-Franz Law, such that the ZT value using the metal cannot be improved.

Meanwhile, thermoelectric devices using body heat and radioactive heat as the heat sources thereof have come into the market owing to steady research of scientists for semiconductor materials. However, a market scale thereof is insignificant up to now. As the materials for the fabricated thermoelectric device, Bi₂Te₃ has been used at room temperature and moderate temperature and SiGe has been used at high temperature. The ZT value of Bi₂Te₃ is 0.7 at room temperature and 0.9 that is a maximum value at 120° C. The ZT value of SiGe is about 0.1 at room temperature and 0.9 that is a maximum value at 900° C.

Research based on silicon that is a basic material of a semiconductor industry has also been interested. The silicon has very high thermal conductivity as 150 W/m·K and the ZT value of 0.01 and therefore, is difficult to use as the thermoelectric device. However, it is reported to Nature that in case of a silicon nanowire grown through chemical vapor deposition (CVD), the thermal conductivity may be reduced to 0.01 times or less and therefore, the ZT value approaches 1.

The structure of the thermoelectric device according to the related art may be classified into two structures, that is, a lateral structure and a vertical structure. The thermoelectric device having the vertical structure has a structure in which the heat absorbing part, the leg, and the heat radiating part are disposed vertically. Therefore, in the thermoelectric device having the vertical structure, the heat absorbing part and the heat radiating part may be easily separated thermally from each other but the heat absorbing part, the leg, and the heat radiating part each need to be separately fabricated. The thermoelectric device having the lateral structure does not have a structure in which the heat absorbing part, the leg, and the heat radiating part are disposed vertically. That is, the heat absorbing part, the leg, and the heat radiating part may be disposed on the same plane. Therefore, in the thermoelectric device having the lateral structure, the heat absorbing part, the leg, and the heat radiating part may be fabricated at a time, but the heat absorbing part and the heat radiating part may easily reach thermal balance.

### SUMMARY

The present disclosure has been made in an effort to provide a thermoelectric device and a fabricating method thereof capable of obtaining excellent thermoelectric characteristics by maintaining a predetermined temperature difference while preventing a heat absorbing part and a heat radiating part from easily reaching thermal balance.

An exemplary embodiment of the present disclosure provides a thermoelectric device, including: a substrate; a heat absorbing part, a leg, and a heat radiating part formed on the substrate; and a heat radiating material formed between the substrate and the heat radiating part to radiate heat transferred from the heat radiating part.

Another exemplary embodiment of the present disclosure provides a fabricating method of a thermoelectric device, including: forming an oxide film and a heat radiating material on a substrate; forming a heat absorbing part and a leg on the oxide film and forming a heat radiating part on the heat radiating material; and removing the oxide film.

Yet another exemplary embodiment of the present disclosure provides a fabricating method of a thermoelectric device, including: forming an oxide film on a substrate; forming a heat absorbing part, a leg, and a heat radiating part on the oxide film; removing the oxide film; and forming a heat radiating material between the substrate and the heat radiating part.

As set forth above, according to the exemplary embodiments of the present disclosure, it is possible to provide the thermoelectric device having the lateral structure having the excellent heat radiating efficiency and thermoelectric characteristics by providing the thermoelectric device in which the heat radiating material is directly or indirectly thermally connected to the heat radiating part and the fabricating method thereof.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a diagram showing a configuration of a generally used thermoelectric device.

FIG. 2 is a cross-sectional view showing a configuration of a thermoelectric device according to a first exemplary embodiment of the present disclosure.

FIGS. 3A to 3D are process flow charts showing a fabricating method of a thermoelectric device according to a second exemplary embodiment of the present disclosure.

FIGS. 4A to 4D are process flow charts showing a fabricating method of a thermoelectric device according to a third exemplary embodiment of the present disclosure.

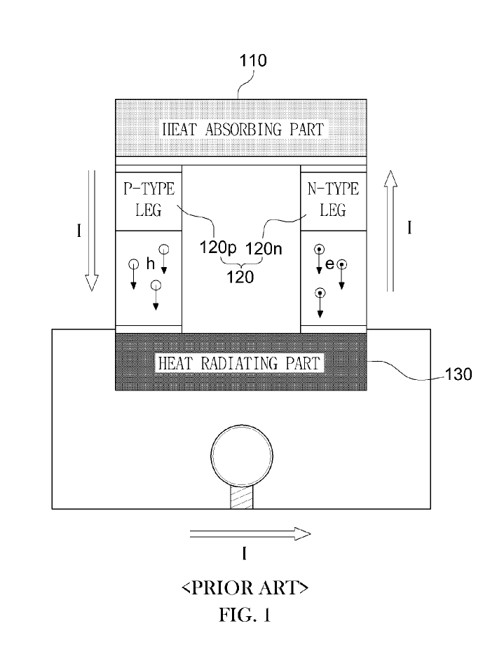

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made, without departing from the spirit or scope of the subject matter presented here.

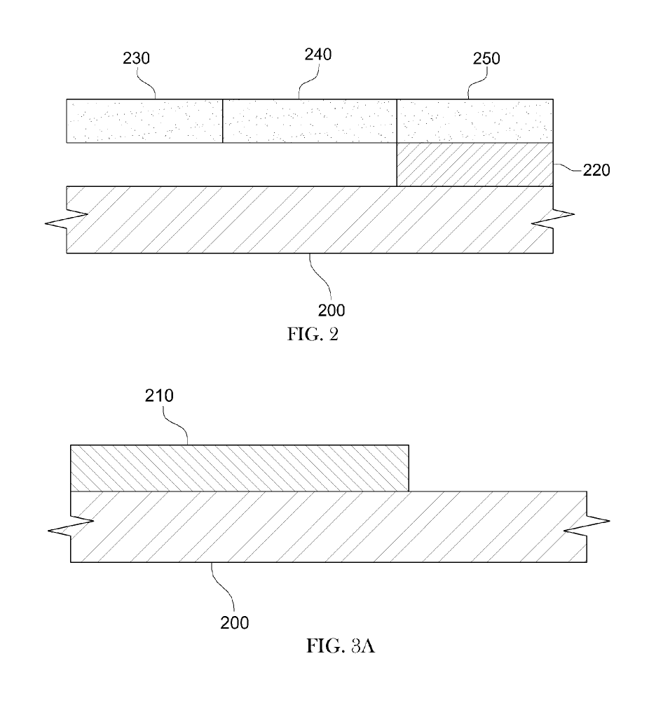

FIG. 2 is a cross-sectional view showing a configuration of a thermoelectric device according to a first exemplary embodiment of the present disclosure.

Referring to FIG. 2, the thermoelectric device according to the exemplary embodiment of the present disclosure includes a substrate 200, a heat radiating material 220, a heat absorbing part 230, a leg 240, a heat radiating part 250, and the like.

The substrate 200 may be a silicon substrate, a silicon on insulator (SOI) substrate, and the like.

The heat radiating material 220 is formed on one side of an upper portion of the substrate 200 and radiates heat transferred from the heat radiating part 250. In detail, the heat radiating material 220 is formed between the heat radiating part 250 and the substrate 200.

A part or the whole of the heat radiating material 220 may contact a part or the whole of the heat radiating part 250, such that heat may be transferred to the heat radiating material 220 from the heat radiating part 250. Even when the heat radiating part 250 and the heat radiating material 220 have another material, a space, or a gap formed therebetween so as not to contact each other, heat may be transferred from the heat radiating part 250 to the heat radiating material 220.

At least one probe is present between a part or the whole of the heat radiating part 250 and a part or the whole of the heat radiating material 220, and thus, heat may be transferred from the heat radiating part 250 to the probe and from the probe to the heat radiating material 220.

The heat radiating material 220 is configured in a probe form, and a part or the whole of the heat radiating part 250 is thermally connected to the heat radiating material 220 having a probe form, and thus, heat may be transferred from the heat radiating part 250 to the heat radiating material 220.

The heat radiating material 220 may be formed of a material including at least one of Ag, Cu, Au, Al, W, Ti, Co, Si, Ge, C, O, and N or a graphene material.

The heat absorbing part 230 is formed above the substrate 200 while being spaced apart from the substrate 200 at a predetermined distance and serves to absorb heat from the outside. In this case, an empty space or a material having low thermal conductivity may be present between the substrate 200 and the heat absorbing part 230.

Like the heat absorbing unit 230, the leg 240 is spaced apart from the substrate 200 at a predetermined distance and is formed above the substrate 200. In this case, an empty space or a material having low thermal conductivity may be present between the substrate 200 and the leg 240. One end of the leg 240 is connected with the heat absorbing part 230 and the other end of the leg 240 is connected with the heat radiating part 250, such that the heat absorbing part 230, the leg 240, and the heat radiating part 250 may be laterally connected with one another. Therefore, heat transferred from the heat absorbing part 230 is transferred to the heat radiating part 250 through the leg 240. Herein, the leg 240 may be formed of a material including at least one of Te, Si, Sb, O, C, and Ge or a graphene material.

As described above, in the thermoelectric device according to the exemplary embodiment of the present disclosure, the heat absorbing part 230 and the leg 240 are spaced apart from the substrate 200 at predetermined distances, such that the empty space or the material having low thermal conductivity is present between the substrate 200 and the heat absorbing part 230 and between the substrate 200 and the leg 240. Since the thermal conductivity of air is low, which is about 1/100 of the thermal conductivity of an oxide film 210, the heat transfer from the heat absorbing part 230 to the leg 240 and from the leg 240 to the heat radiating part 250 is more activated.

The heat radiating part 250 is formed on the heat radiating material 220 and radiates the heat transferred from the leg 240 through the heat radiating material 220.

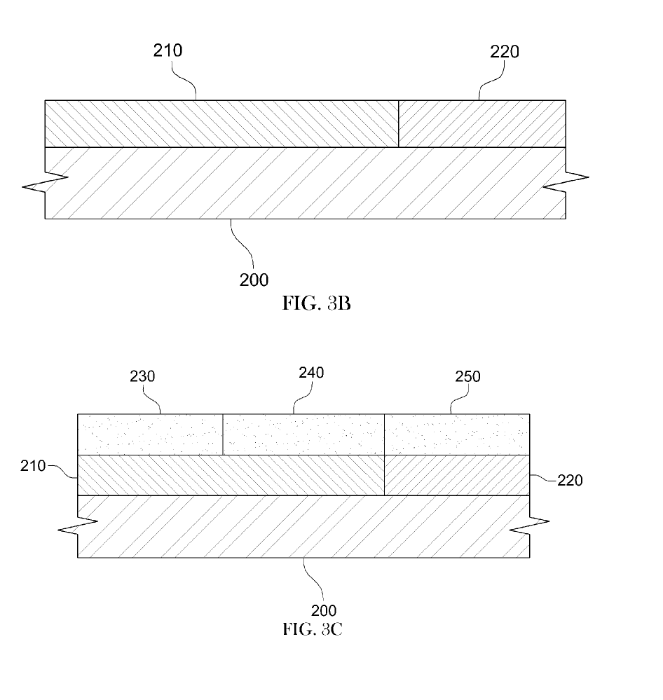

FIGS. 3A to 3D are process flow charts showing a fabricating method of a thermoelectric device according to a second exemplary embodiment of the present disclosure.

Referring to FIG. 3A, the oxide film 210 is formed on the substrate 200. Here, the substrate 200 may be a silicon substrate, a silicon on insulator (SOI) substrate, and the like.

Referring to FIG. 3B, the heat radiating material 220 is further formed on the substrate 200. Here, the heat radiating material 220 may be formed of a material including at least one of Ag, Cu, Au, Al, W, Ti, Co, Si, Ge, C, 0, and N or a graphene material.

Referring to FIG. 3C, the heat absorbing part 230 and the leg 240 are formed on the oxide film 210 and the heat radiating part 250 is formed on the heat radiating material 220. In this case, one end of the leg 240 is connected with the heat absorbing part 230 and the other end of the leg 240 is connected with the heat radiating part 250. Therefore, the heat absorbing part 230, the leg 240, and the heat radiating part 250 are laterally connected with one another. Herein, the leg 240 may be formed of a material including at least one of Te, Si, Sb, O, C, and Ge or a graphene material.

Referring to FIG. 3D, the oxide film 210 is removed. Therefore, the empty space is present between the substrate 200 and the heat absorbing part 230 and between the substrate 200 and the leg 240. Since the thermal conductivity of air is about 1/100 than that of the oxide film 210, the heat transfer from the heat absorbing part 230 to the leg 240 and from the leg 240 to the heat radiating part 250 is more activated.

A process of forming the material having low thermal conductivity between the substrate 200 and the heat absorbing part 230 and between the substrate 200 and the leg 240 is further included, so that the material having low thermal conductivity may also be present between the substrate 200 and the heat absorbing part 230 and between the substrate 200 and the leg 240.

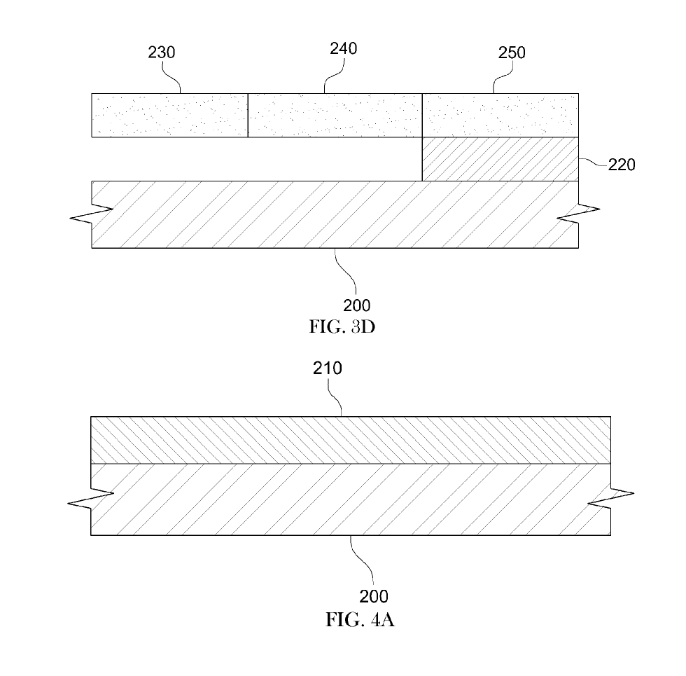

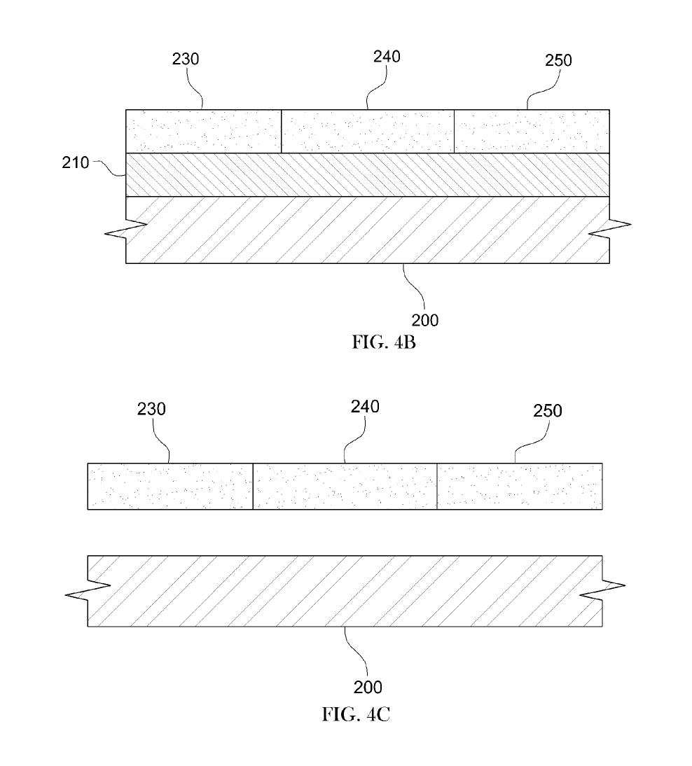

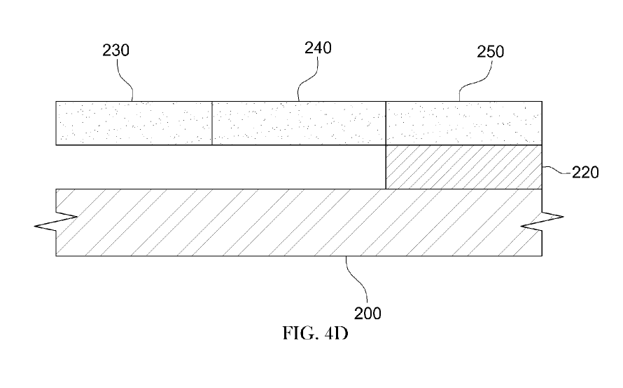

FIGS. 4A to 4D are process flow charts showing a fabricating method of a thermoelectric device according to a third exemplary embodiment of the present disclosure.

Referring to FIG. 4A, the oxide film 210 is formed on the substrate 200. Here, the substrate 200 may be a silicon substrate, a silicon on insulator (SOI) substrate, and the like.

Referring to FIG. 4B, the heat absorbing part 230, the leg 240, and the heat radiating part 250 are formed on the oxide film 210. In this case, one end of the leg 240 is connected with the heat absorbing part 230 and the other end of the leg 240 is connected with the heat radiating part 250. The heat absorbing part 230, the leg 240, and the heat radiating part 250 are laterally connected with one another. Herein, the leg 240 may be formed of a material including at least one of Te, Si, Sb, O, C, and Ge or a graphene material.

Referring to FIG. 4C, the oxide film 210 is removed.

Referring to FIG. 4D, the heat radiating material 220 is filled between the substrate 220 and the heat radiating part 250. Here, the heat radiating material 220 may be formed of a material including at least one of Ag, Cu, Au, Al, W, Ti, Co, Si, Ge, C, O, and N or a graphene material.

Therefore, the empty space is present between the substrate 200 and the heat absorbing part 230 and between the substrate 200 and the leg 240. Consequently, since the thermal conductivity of air is about 1/100 lower than that of of the oxide film 210, the heat transfer from the heat absorbing part 230 to the leg 240 and from the leg 240 to the heat radiating part 250 is more activated.

A process of forming the material having low thermal conductivity between the substrate 200 and the heat absorbing part 230 and between the substrate 200 and the leg 240 is further included, so that the material having low thermal conductivity may also be present between the substrate 200 and the heat absorbing part 230 and between the substrate 200 and the leg 240.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A thermoelectric device, comprising:
a substrate;
a heat absorbing part, a leg, and a heat radiating part formed on the substrate; and
a heat radiating material formed between the substrate and the heat radiating part to radiate heat transferred from the heat radiating part.

2. The thermoelectric device of claim 1, wherein one end of the leg is connected with the heat absorbing part and the other end of the leg is connected with the heat radiating part.

3. The thermoelectric device of claim 1, wherein the heat absorbing part, the leg, and the heat radiating part are laterally connected with one another.

4. The thermoelectric device of claim 1, wherein a part or the whole of the heat radiating part contacts a part or the whole of the heat radiating material.

5. The thermoelectric device of claim 1, wherein another material or an empty space is present between a part or the whole of the heat radiating part and a part or the whole of the heat radiating material.

6. The thermoelectric device of claim 1, wherein at least one probe transferring heat radiated from the heat radiating part to the heat radiating material is present between a part or the whole of the heat radiating part and a part or the whole of the heat radiating material.

7. The thermoelectric device of claim 1, wherein the heat radiating material is configured in a probe form and is connected with a part or the whole of the heat radiating part.

8. The thermoelectric device of claim 1, wherein the leg is formed of a material including at least one of Te, Si, Sb, O, C, and Ge or a graphene material.

9. The thermoelectric device of claim 1, wherein the heat radiating material is formed of a material including at least one of Ag, Cu, Au, Al, W, Ti, Co, Si, Ge, C, O, and N or a graphene material.

10. The thermoelectric device of claim 1, wherein an empty space or a material having low thermal conductivity is present between the substrate and the heat absorbing part and between the substrate and the leg.

11. A fabricating method of a thermoelectric device, comprising:
forming an oxide film and a heat radiating material on a substrate;
forming a heat absorbing part and a leg on the oxide film and forming a heat radiating part on the heat radiating material; and
removing the oxide film.

12. The method of claim 11, wherein the heat absorbing part, the leg, and the heat radiating part are laterally connected with one another.

13. The method of claim 11, wherein the heat radiating material is formed of a material including at least one of Ag, Cu, Au, Al, W, Ti, Co, Si, Ge, C, O, and N or a graphene material.

14. The method of claim 11, further comprising:
forming a material having low thermal conductivity between the substrate and the heat absorbing part and between the substrate and the leg.

15. A fabricating method of a thermoelectric device, comprising:
forming an oxide film on a substrate;
forming a heat absorbing part, a leg, and a heat radiating part on the oxide film; removing the oxide film; and
forming a heat radiating material between the substrate and the heat radiating part.

16. The method of claim 15, wherein the heat absorbing part, the leg, and the heat radiating part are laterally connected with one another.

17. The method of claim 15, wherein the heat radiating material is formed of a material including at least one of Ag, Cu, Au, Al, W, Ti, Co, Si, Ge, C, O, and N or a graphene material.

18. The method of claim 15, further comprising:
forming a material having low thermal conductivity between the substrate and the heat absorbing part and between the substrate and the leg.
